(19) United States
(12) Patent Application Publication
(10) Pub. No.: US 2026/0182378 A1
(43) Pub. Date: Jun. 25, 2026

(54) SEMICONDUCTOR DEVICE

(71) Applicant: Mitsubishi Electric Corporation, Tokyo (JP)

(72) Inventor: Tetsuo TAKAHASHI, Tokyo (JP)

(73) Assignee: Mitsubishi Electric Corporation, Tokyo (JP)

(21) Appl. No.: 19/316,810

(22) Filed: Sep. 2, 2025

(30) Foreign Application Priority Data
Dec. 25, 2024 (JP) 2024-229253

(51) Int. Cl. H01L 23/00; H01L 23/31; H01L 23/482

(52) U.S. Cl. CPC H10W 42/00; H10W 20/40; H10W 74/131

(57) ABSTRACT

A semiconductor device according to an aspect of the present disclosure, includes a semiconductor substrate; wiring provided on the semiconductor substrate; and a protective film covering at least a portion of the wiring; wherein the wiring include a first metal layer and a second metal layer provided on the first metal layer, the second metal layer including a metal having higher moisture resistance or acid resistance than the first metal layer, and a contact portion between the first metal layer and the second metal layer in the wiring is not exposed to a member provided on the protective film.

### BACKGROUND

### Field

The present disclosure relates to a semiconductor device.

### BACKGROUND

WO2021/064944 A1 discloses a semiconductor device that can improve insulation reliability. The semiconductor device includes a semiconductor substrate including a drift layer of a first conductivity type and a termination well region formed on a surface layer of the drift layer and having a second conductivity type different from the first conductivity type. A surface electrode made mainly of aluminum is formed on the surface of the semiconductor substrate, with the outer peripheral end face positioned above and in contact with the termination well region, thereby electrically connecting the termination well region. The insulating protective film covers the surface electrode end of the surface electrode and the termination well region, and extends to the outer periphery of the semiconductor substrate. An electrode protective film made of titanium is provided between the surface electrode and the insulating protective film. The electrode protective film and the insulating protective film have openings that open in a position corresponding to the electrode formation region of the surface electrode so as to expose the surface electrode.

Power semiconductor devices, known as power devices, are used in switching devices that control the supply of power to motor loads and the like. Insulated gate semiconductor devices such as metal oxide semiconductor field effect transistors (MOSFETs) and insulated gate bipolar transistors (IGBTs) are widely used as power semiconductor devices. Power devices are becoming increasingly capable of handling large currents, high voltages, and low losses, and are used in a wide range of fields. Power devices are often used in harsh environments such as high altitudes, high temperatures, and high humidity, and therefore require high reliability against temperature cycles, humidity, etc.

In the configuration of WO2021/064944 A1, the end portion of the surface electrode in the Schottky barrier diode, where the electric field is strong, is covered with a protective film made of, for example, Ti, which has high corrosion resistance. This makes it possible to prevent corrosion of the surface electrodes made of aluminum, which is a wiring material that easily corrodes. However, in the configuration of WO2021/064944 A1, since a plurality of metal materials are in contact with each other, there is a possibility that corrosion of the electrodes may occur due to the local battery effect in the presence of moisture.

### SUMMARY

The present disclosure has been made to solve the above-mentioned problems, and has an object to provide a semiconductor device capable of improving moisture resistance or acid resistance.

The features and advantages of the present disclosure may be summarized as follows.

According to an aspect of the first disclosure, a semiconductor device includes a semiconductor substrate; wiring provided on the semiconductor substrate; and a protective film covering at least a portion of the wiring; wherein the wiring include a first metal layer and a second metal layer provided on the first metal layer, the second metal layer including a metal having higher moisture resistance or acid resistance than the first metal layer, and a contact portion between the first metal layer and the second metal layer in the wiring is not exposed to a member provided on the protective film.

According to an aspect of the second disclosure, a semiconductor device includes a semiconductor substrate including an active region, a wiring region outside the active region, and a termination region outside the wiring region; a wiring provided on the wiring region; and a protective film covering at least a portion of the wiring; wherein the wiring include a first metal layer and a second metal layer provided on the first metal layer, the second metal layer including a metal having higher moisture resistance or acid resistance than the first metal layer; and the protective film is provided from an upper surface of the second metal layer to both side surfaces of the first metal layer.

According to an aspect of the third disclosure, a semiconductor device includes a semiconductor substrate; a pad electrode provided on the semiconductor substrate; and a protective film provided on the pad electrode; wherein the pad electrode includes a first metal layer and a second metal layer provided on the first metal layer, the second metal layer including a metal having higher moisture resistance or acid resistance than the first metal layer; a pad opening is formed in the pad electrode, in which the first metal layer is exposed from the second metal layer; and a contact portion between the first metal layer and the second metal layer facing the pad opening is covered with the protective film.

Other and further objects, features and advantages of the disclosure will appear more fully from the following description.

### BRIEF DESCRIPTION OF DRAWINGS

FIG. 1 is a plan view of a semiconductor device according to Embodiment 1.

FIG. 2 is an enlarged view of an active region according to Embodiment 1.

FIG. 3 is a cross-sectional view obtained by cutting FIG. 2 along the line A-B.

FIG. 4 is an enlarged view of an edge region of an active region according to Embodiment 1.

FIG. 5 is a cross-sectional view obtained by cutting FIG. 4 along line C-D.

FIGS. 6 to 21 are cross-sectional views illustrating a method for manufacturing the semiconductor device according to Embodiment 1.

FIG. 22 is an enlarged view of an edge region of an active region according to Embodiment 2.

FIG. 23 is a cross-sectional view taken along line C-D of FIG. 22.

FIG. 24 is an enlarged view of an edge region of an active region according to Embodiment 3.

FIG. 25 is a cross-sectional view taken along line C-D of FIG. 24.

FIG. 26 is an enlarged view of an edge region of an active region according to Embodiment 4.

FIG. 27 is a cross-sectional view obtained by cutting FIG. 26 along line C-D.

FIG. 28 is a plan view of a semiconductor device according to Embodiment 5.

FIG. 29 is an enlarged view of an edge region of an active region according to Embodiment 5.

FIG. 30 is a cross-sectional view obtained by cutting FIG. 29 along line E-F.

### DESCRIPTION OF EMBODIMENTS

Semiconductor devices according to the respective embodiments will be described with reference to the drawings. The same or corresponding components are given the same symbols and repeated descriptions may be omitted.

### Embodiment 1

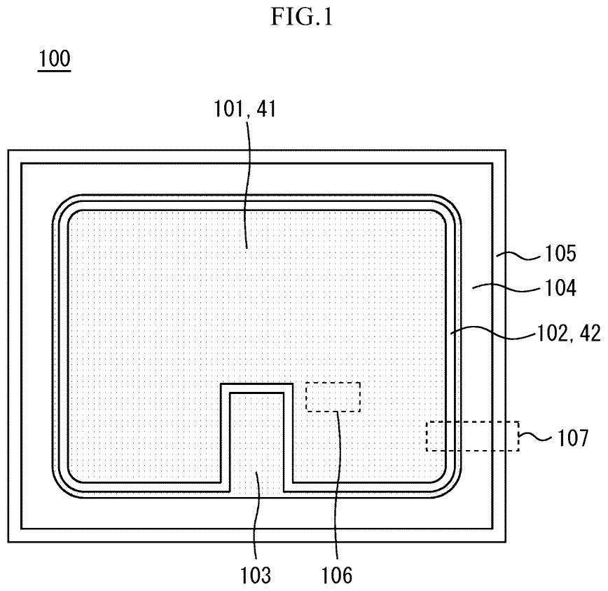

FIG. 1 is a plan view of a semiconductor device 100 according to Embodiment 1. The semiconductor substrate of the semiconductor device 100 has an active region 101, a gate wiring region 102 outside the active region 101, and a termination region 104 outside the gate wiring. A main electrode of the semiconductor device 100 is formed on the upper surface of the active region 101. The main electrode is, for example, a source electrode. The main electrode corresponds to a pad electrode 41 which will be described later.

In a gate wiring region 102 surrounding the active region 101, a gate wiring 42 is provided which is electrically connected to a gate electrode serving as a control electrode. The gate wiring 42 is connected to a gate pad 103. A termination region 104 for maintaining a breakdown voltage is formed so as to surround the active region 101, the gate wiring region 102 and the gate pad 103. A dicing line region 105 corresponding to the dicing lines used when cutting out chips is provided so as to surround the termination region 104.

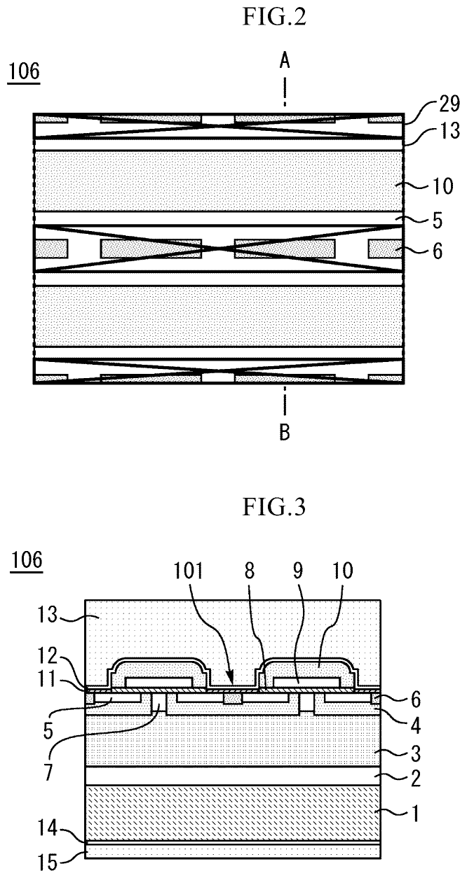

FIG. 2 is an enlarged view of the active region 101 according to Embodiment 1. FIG. 2 is an enlarged view of region 106 in FIG. 1. FIG. 3 is a cross-sectional view obtained by cutting FIG. 2 along the line A-B. As shown in FIG. 3, the semiconductor device 100 includes an n+ type semiconductor substrate 1. An n+ type buffer layer 2 is formed on a semiconductor substrate 1. An n− type drift layer 3 is formed on the upper surface side of the buffer layer 2. A p− type well layer 4 is selectively formed on the upper surface side of the drift layer 3. An n+ type source layer 5 and a p+ type contact layer 6 are formed on the upper surface side of the well layer 4. Between the well layers 4, an n− type JFET doped layer 7 is formed.

A gate insulating film 8 is provided on the well layer 4, the source layer 5 and the JFET doped layer 7 on the upper surface of the semiconductor substrate 1. A gate electrode layer 9 is provided on the gate insulating film 8. The gate electrode layer 9 is made of, for example, polysilicon. An interlayer insulating film 10 is formed on the gate electrode layer 9. On the upper surface of the semiconductor substrate 1, a Ni silicide layer 11 is formed on the source layer 5 and the contact layer 6. A barrier metal layer 12 is provided on the Ni silicide layer 11 and the interlayer insulating film 10. The barrier metal layer 12 is made of, for example, Ti/TiN. A metal layer 13 is formed on the barrier metal layer 12. The metal layer 13 is, for example, an Al electrode. The Ni silicide layer 11, the barrier metal layer 12 and the metal layer 13 may be collectively referred to as a source electrode or a pad electrode 41.

A Ni silicide layer 14 is formed on the rear surface of the semiconductor substrate 1. An Al electrode 15 is formed on the rear surface of the Ni silicide layer 14. The Ni silicide layer 14 and the Al electrode 15 may be collectively called a drain electrode.

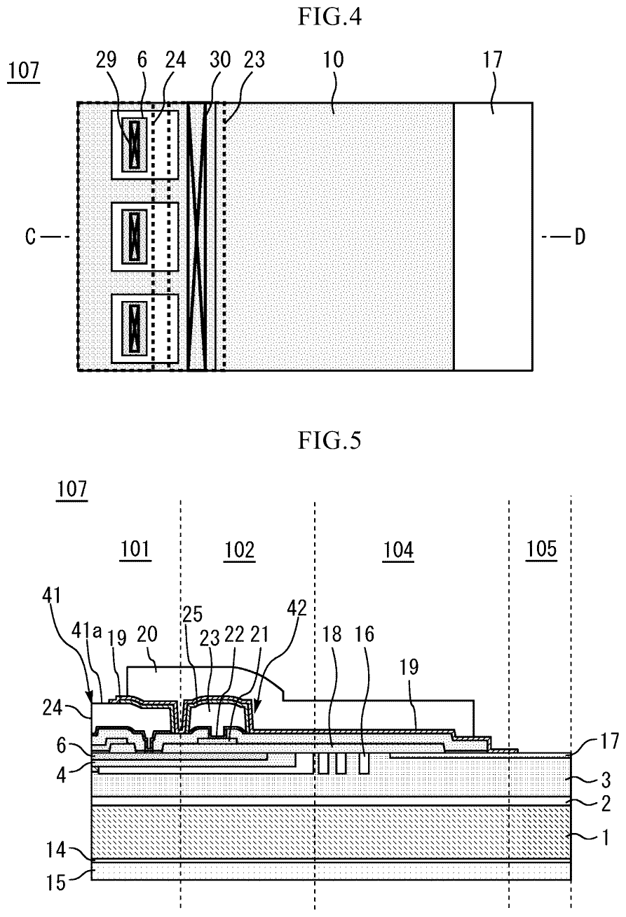

FIG. 4 is an enlarged view of an edge region 107 of the active region 101 according to Embodiment 1. FIG. 5 is a cross-sectional view obtained by cutting FIG. 4 along line C-D. As shown in FIG. 5, in the termination region 104, on the upper surface side of drift layer 3, a p type field limiting ring (FLR) layer 16 and an n+ type channel stopper layer 17 are formed. In this manner, a breakdown voltage holding structure called an FLR structure is formed in the termination region 104. In the termination region 104, a field insulating film 18 is formed on the upper surface of the semiconductor substrate 1. A protective film 19 such as a nitride film is formed on the field insulating film 18. On the protective film 19, a protective film 20 such as a polyimide film is formed. The protective film 19 is, for example, an inorganic protective film that has excellent moisture resistance and a moisture permeation prevention function. The protective film 20 is, for example, an organic protective film having a stress relaxation function.

In the gate wiring region 102, a gate electrode 21 is formed on the field insulating film 18. The gate electrode 21 is a wiring layer connected to the gate electrode layer 9. The gate electrode 21 is made of polysilicon. A barrier metal layer 22 is formed on the gate electrode 21. The barrier metal layer 22 is formed of, for example, Ti silicide/TiN. A metal layer 23 is formed on the barrier metal layer 22. The metal layer 23 is made of, for example, Al. In the active region 101, a metal layer 24 is formed on the field insulating film 18 with the barrier metal layer 22 interposed therebetween. The metal layer 24 is made of, for example, Al.

A metal layer 25 serving as an electrode protective film is formed on the metal layers 23 and 24. The metal layer 25 is made of, for example, Ti. The barrier metal layer 22, the metal layer 23, and the metal layer 25 provided on the metal layer 23 constitute the gate wiring 42. The barrier metal layer 22, the metal layer 24, and the metal layer 25 provided on the metal layer 24 constitute the pad electrode 41. The protective films 19 and 20 are formed on the metal layer 25. The protective films 19 and 20 cover the entire gate wiring 42 and the end of the pad electrode 41.

In the semiconductor device 100, the source electrode is formed on the upper surface of the semiconductor substrate 1, and the drain electrode is formed on the rear surface of the semiconductor substrate 1. As a result, a main current flows in the vertical direction of the semiconductor substrate 1. In a MOSFET constituted by the source layer 5, the well layer 4, the drift layer 3, the gate insulating film 8, and the gate electrode layer 9, the main current is controlled by the gate.

As shown in FIG. 2, the unit cells are formed in a stripe pattern. The gate electrode layers 9 are also formed in a stripe pattern. The gate electrode layer 9 is connected to a gate electrode 21 in the gate wiring region 102 adjacent to an end of the active region 101. In the contact hole 30 surrounded by X shown in FIG. 4, the gate electrode 21 is connected to the gate wiring 42. Furthermore, the semiconductor substrate 1 and the pad electrode 41 are in contact with each other in the contact hole 29 surrounded by X shown in FIGS. 2, 4. This causes the source to be grounded.

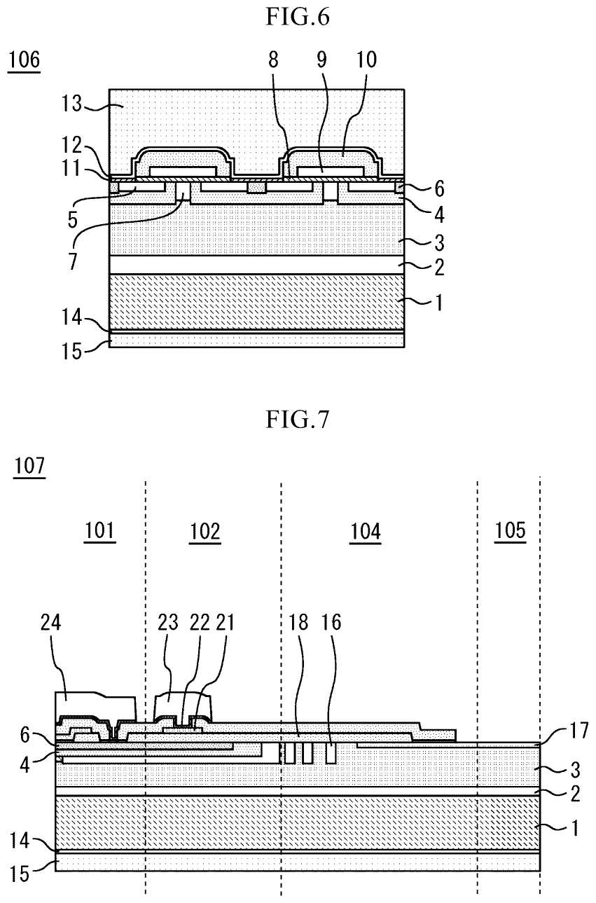

Next, a method for manufacturing the semiconductor device 100 will be described. FIGS. 6 to 21 are cross-sectional views illustrating a manufacturing method of the semiconductor device 100 according to Embodiment 1. FIGS. 6 and 7 are respectively an A-B cross-sectional view of the active region 101 and a C-D cross-sectional view of the peripheral region after the steps of forming the diffusion layers, MOS gates, interlayer films, and wiring have been completed. The steps up to this point can be performed by a general semiconductor process, so a description thereof will be omitted.

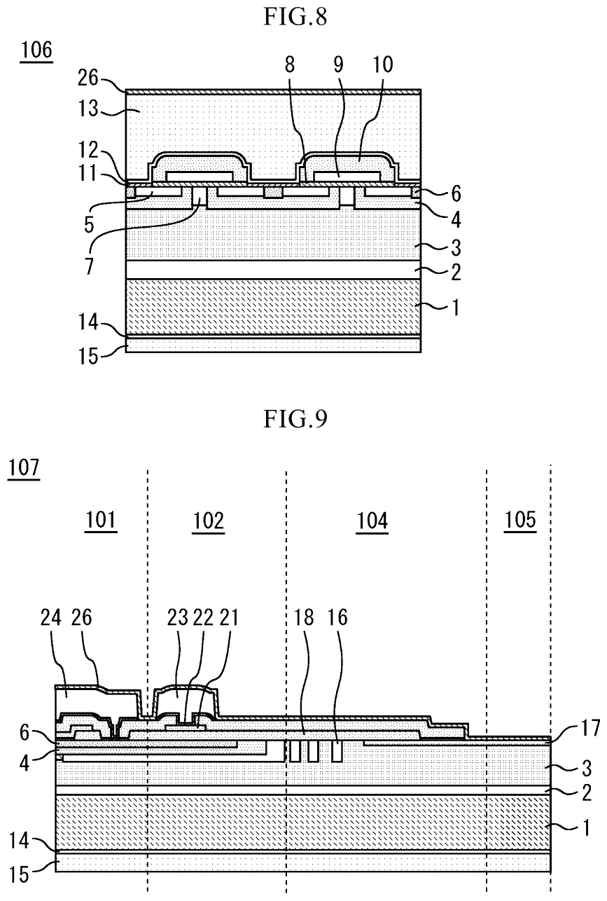

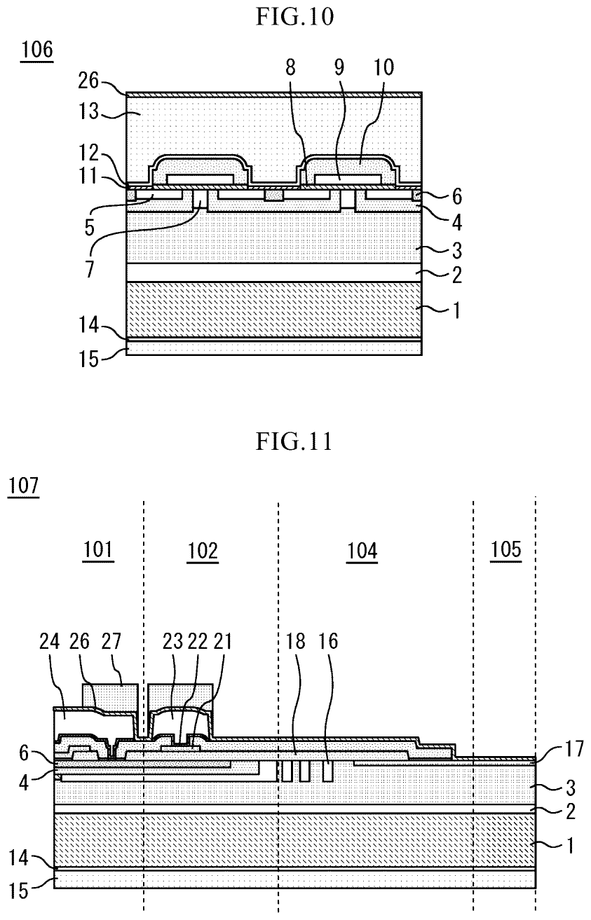

Next, a Ti film 26 is formed on the metal layers 13 and 24 by using a sputtering technique or the like. FIGS. 8 and 9 are cross-sectional views taken along lines A-B and C-D, respectively, in a state in which the Ti film 26 has been formed. Next, resist patterning is performed using a general photolithography technique. FIGS. 10 and 11 are cross-sectional views taken along lines A-B and C-D, respectively, in a state in which the resist 27 has been patterned.

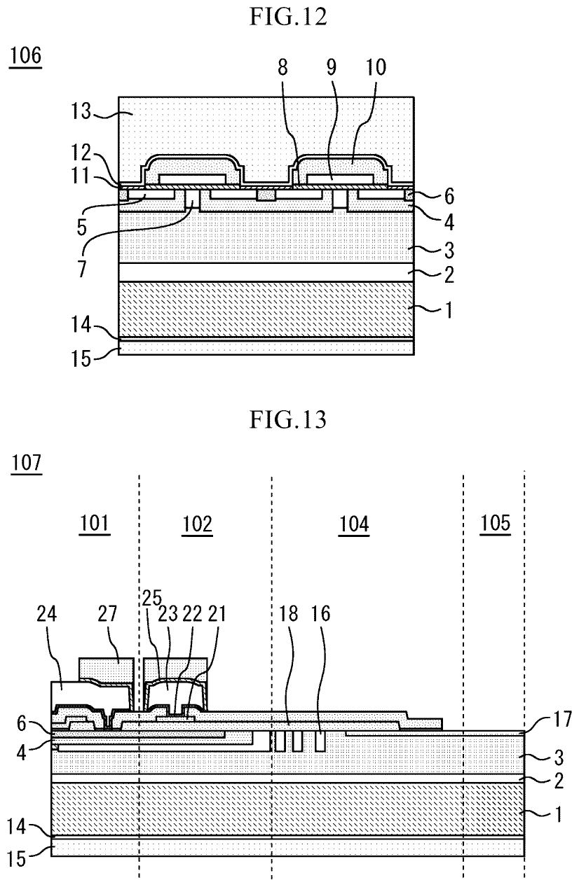

Next, the Ti film 26 is etched using the resist 27 as a mask. As a result, the metal layer 25 is formed at the predetermined position. FIGS. 12 and 13 are cross-sectional views taken along lines A-B and C-D, respectively, in a state in which the metal layer 25 has been formed. At this time, the size, position, etc. of the resist 27 are adjusted as necessary so that the metal layer 25 can cover the metal layers 23 and 24.

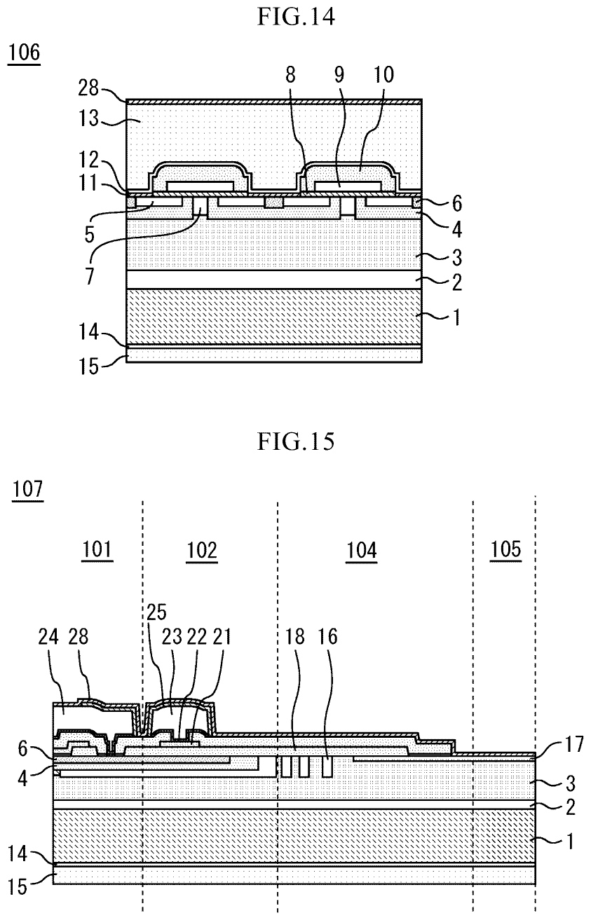

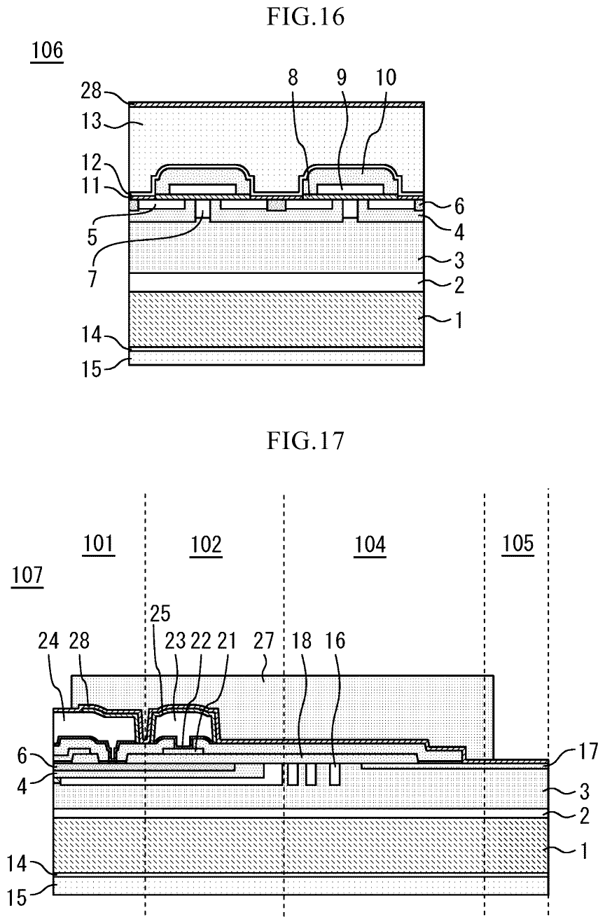

Next, after removing the resist 27, a nitride film 28 is formed by using a method such as deposition. FIGS. 14 and 15 are cross-sectional views taken along lines A-B and C-D, respectively, in a state in which the nitride film 28 has been formed. Furthermore, resist patterning is performed using a general photolithography technique. FIGS. 16 and 17 are cross-sectional views taken along lines A-B and C-D, respectively, in a state where the resist 27 has been formed.

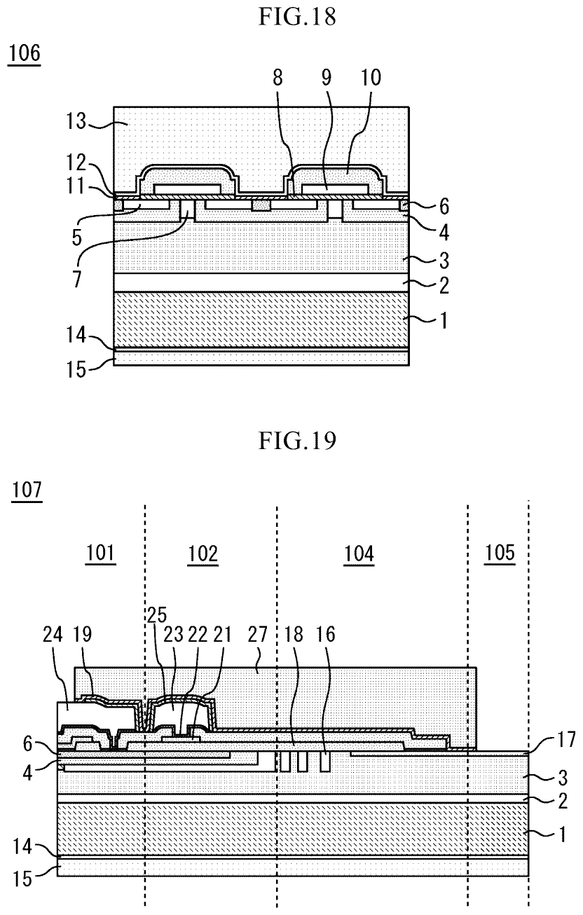

Next, the nitride film 28 is etched using the resist 27 as a mask to form the protective film 19 at a predetermined position. FIGS. 18 and 19 are cross-sectional views taken along lines A-B and C-D, respectively, in a state in which the protective film 19 has been formed. At this time, the size, position, etc. of the resist 27 are adjusted so that the area where the metal layer 23 or the metal layer 24 and the metal layer 25 are in contact with each other is entirely covered with the protective film 19.

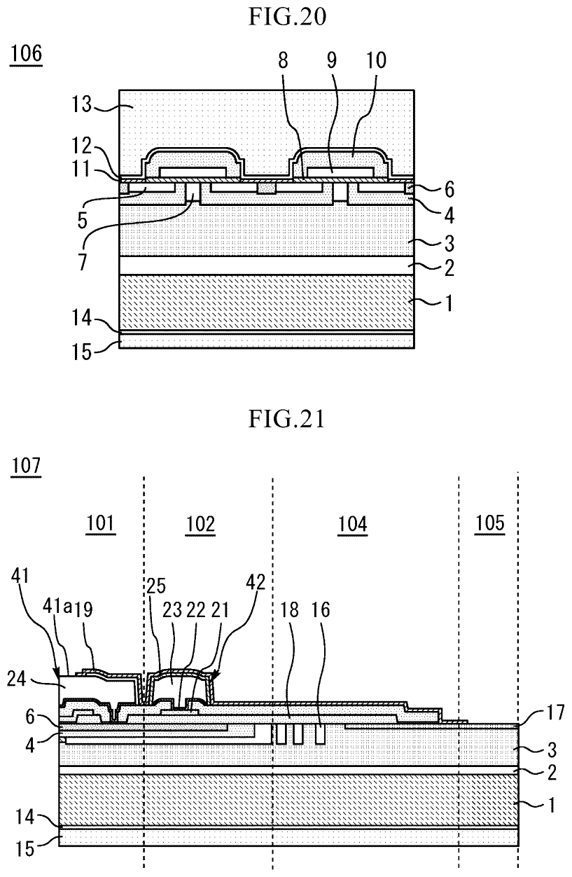

Next, the resist 27 is removed. FIGS. 20 and 21 are cross-sectional views taken along lines A-B and C-D, respectively, in a state in which the resist 27 has been removed. The subsequent steps can be performed by a general semiconductor process, so a description thereof will be omitted.

Next, the operation of the semiconductor device 100 will be described. When a positive voltage applied to the gate pad 103 becomes equal to or greater than the threshold voltage of the MOSFET, the MOSFET turns on. As a result, the drain voltage drops, a main current flows between the source and drain, and the semiconductor device 100 enters an ON state. Conversely, when the negative voltage applied to the gate pad 103 in the on state becomes equal to or lower than the threshold voltage, the MOSFET turns off. As a result, the current between the source and drain is cut off, the drain voltage rises, and the semiconductor device 100 enters an OFF state.

In the off state, in the termination region 104, a depletion layer extends laterally from the active region 101 side toward the end of the termination region 104. At this time, the electric field intensity is set to a predetermined value or less by the FLR layer 16 and the channel stopper layer 17. Therefore, the gate wiring 42 formed in the region closest to the termination region 104 at the end of the active region 101 is more susceptible to the influence of the drain voltage than the active region 101.

Furthermore, in high temperature and humidity environments, moisture may enter the device while ionizing from the outside. In particular, in transfer molded products, there is a risk of moisture penetrating from the chip end through the resin interface. Thus, particularly in the periphery of the chip, the metal layer 23 of the gate wiring 42 made of Al is more susceptible to corrosion than other portions due to the effects of temperature, humidity, and electric field.

In contrast, in this embodiment, the metal layer 23 made of Al is covered with the metal layer 25 which is a Ti electrode having excellent corrosion resistance. Therefore, it is possible to improve the moisture resistance or acid resistance, and improve the THB (Temperature Humidity Bias) resistance.

Furthermore, in the gate wiring 42, the upper surface and both side surfaces of the metal layer 23 are entirely covered with the metal layer 25. In other words, the contact portion between the metal layer 23 and the metal layer 25 is not exposed to the member provided on the protective film 19. This makes it possible to prevent the contact portion between two types of metals such as Al and Ti from being exposed to the protective film 20, the sealing resin, etc., and from being exposed to moisture. Therefore, it is possible to suppress metal corrosion caused by the local battery effect, and it is possible to further improve moisture resistance or acid resistance.

Furthermore, the gate wiring 42 is covered with a protective film 19. This makes it possible to further suppress the intrusion of moisture, and improve the moisture resistance or acid resistance. In particular, by covering the entire upper surface and both side surfaces of the gate wiring 42 with the protective film 19, it is possible to further improve the moisture resistance or acid resistance.

Also, a part of the active region 101 needs to be bonded to an electrode of the package by a method such as wire bonding or solder bonding. Therefore, parts of the metal layers 13 and 24 are exposed. That is, the pad electrode 41 has a pad opening 41 a where the metal layer 24 is exposed from the metal layer 25. In the pad opening 41 a, the metal layer 24 is not covered with the metal layer 25. Therefore, there is a risk that the contact portion between the metal layers 24 and 25, that is, the end portion of the metal layer 25, may be exposed at a position facing the pad opening 41a.

In contrast, in this embodiment, the contact portion between the metal layer 24 and the metal layer 25 facing the pad opening 41 a is covered with the protective film 19. That is, in the pad electrode 41, the contact portion between the metal layer 24 and the metal layer 25 is not exposed to the member provided on the protective film 19. Therefore, galvanic corrosion and local battery effect can be prevented, and moisture resistance or acid resistance can be further improved.

In this embodiment, the protective film 20 which is a polyimide film is further provided on the protective film 19. This makes it possible to alleviate stress, particularly in mold-sealed products. In addition, the protective film 20 covers the corners of the gate wiring 42 and the pad electrode 41. This makes it possible to alleviate stress in areas where stress is likely to be applied, such as steps in the wiring.

In this embodiment, the metal layer 25 is made of Ti. It is desirable to set the thickness of this Ti film so that no pinholes are generated, and taking into consideration the effect on etching and wafer warpage, it is desirable to set the thickness to about 200 to 3000 Å. Moreover, the metal layer 25 may be formed of a material containing Ti, Au, or Pt, which has excellent moisture resistance. The metal layer 25 may contain a metal having higher moisture resistance or acid resistance than the metal layers 23 and 24.

In this embodiment, the metal layers 23 and 24 are made of Al. However, the metal layers 23 and 24 may contain Al or Cu. The metal layers 23 and 24 are not limited to pure Al, but may be AlSi or AlSiCu, or may be wiring mainly made of Cu.

The thickness of the nitride film as the protective film 19 is desirably set to a thickness that will not cause cracks in the film under the operating temperature conditions, and is desirably about 5000 to 30000 Å, taking into consideration the effect on etching and wafer warpage. The protective film 19 may be an oxide film. The protective film 19 may be a glass coat such as a plasma nitride film or a plasma oxide film.

In this embodiment, in the gate wiring 42 provided closest to the termination region 104 in the gate wiring region 102, the contact portion between the metal layer 23 and the metal layer 24 is not exposed to the member provided on the protective film 19. Without being limited to this, it is sufficient that in any of the wiring provided in the wiring region between the active region 101 and the termination region 104, the contact portion between the metal layer 23 and the metal layer 24 is not exposed to the member provided on the protective film 19.

Such a configuration in which the contact portion of different metal layers is not exposed may be applied to any wiring on the semiconductor substrate 1. As described above, the configuration in which the contact portions of different metal layers are not exposed is particularly effective when applied to wiring on the periphery of a chip, but the effect of improving moisture resistance and acid resistance can be obtained regardless of whether it is applied to any wiring.

For example, a configuration in which the contact portion between the metal layer 24 and the metal layer 25 is not exposed may be applied to the pad electrode 41, and the above configuration may not be applied to the gate wiring 42. Similarly, a configuration in which the contact portion between the metal layer 23 and the metal layer 25 is not exposed may be applied to the gate wiring 42, and the above configuration may not be applied to the pad electrode 41. In addition, “the contact portion of the different metal layers is not exposed to the member provided on the protective film” means that the end portion of the contact surface of the different metal layers is not exposed to the member provided on the protective film 19.

In the example of FIG. 5, the upper surface and both side surfaces of the gate wiring 42 are entirely covered with the protective film 19. The protective film 19 is not limited to this, and it is sufficient that the protective film 19 covers at least a part of the gate wiring 42. For example, the protective film 19 may be provided so as to extend from the upper surface of the metal layer 25 to both side surfaces of the metal layer 23 and cover only a portion of the gate wiring 42. This configuration also makes it possible to improve the moisture resistance or acid resistance by the metal layer 25 and the protective film 19. It is preferable that the contact portion between the metal layers 23 and 25 and the contact portion between the metal layers 24 and 25 are not exposed, but a part of them may be exposed within an allowable range.

The semiconductor substrate 1 may be a silicon substrate, or may be made of a wide band gap semiconductor. The wide band gap semiconductor is silicon carbide, a gallium nitride based material or diamond. Furthermore, the semiconductor device 100 is not limited to a MOSFET, but may be another device such as an IGBT.

The above-mentioned modifications can be appropriately applied to the semiconductor device according to the following embodiments. The semiconductor device according to the following embodiments has many points in common with Embodiment 1, so the following description will focus on the points of difference from Embodiment 1.

### Embodiment 2

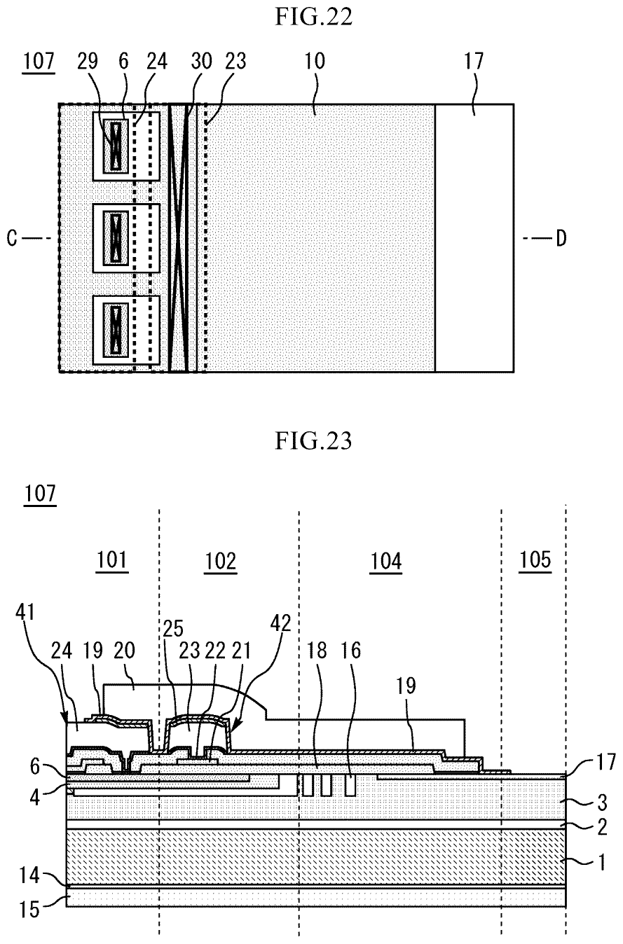

FIG. 22 is an enlarged view of the edge region 107 of the active region 101 according to Embodiment 2. FIG. 23 is a cross-sectional view obtained by cutting FIG. 22 along line C-D. This embodiment differs from Embodiment 1 in that metal layer 25 is provided only on the upper surfaces of metal layers 23 and 24. In other words, the side surfaces of the metal layer 23 and the side surfaces of the metal layer 24 are exposed from the metal layer 25. The other configuration is the same as that of Embodiment 1.

In this embodiment, the metal layers 23 and 24 are partially covered with the metal layer 25 to improve moisture resistance. In addition, in the gate wiring 42, the protective film 19 is provided from the upper surface of the metal layer 25 to both side surfaces of the metal layer 23. Therefore, even when the metal layer 25 is provided only on the upper surface of the metal layer 23, the end of the contact surface between the metal layer 23 and the metal layer 25 can be covered with the protective film 19. The end of the contact surface between the metal layer 24 and the metal layer 25 is also covered with the protective film 19. Therefore, the moisture resistance or acid resistance can be improved.

As in Embodiment 1, the protective film 19 does not need to cover the entire gate wiring 42. The protective film 19 may be provided from the upper surface of the metal layer 25 to both side surfaces of the metal layer 23. Moreover, the protective film 19 may be provided from the upper surface of the metal layer 25 to the side surface of the metal layer 24. This allows the end portion of the metal layer 25 to be covered with the protective film 19.

### Embodiment 3

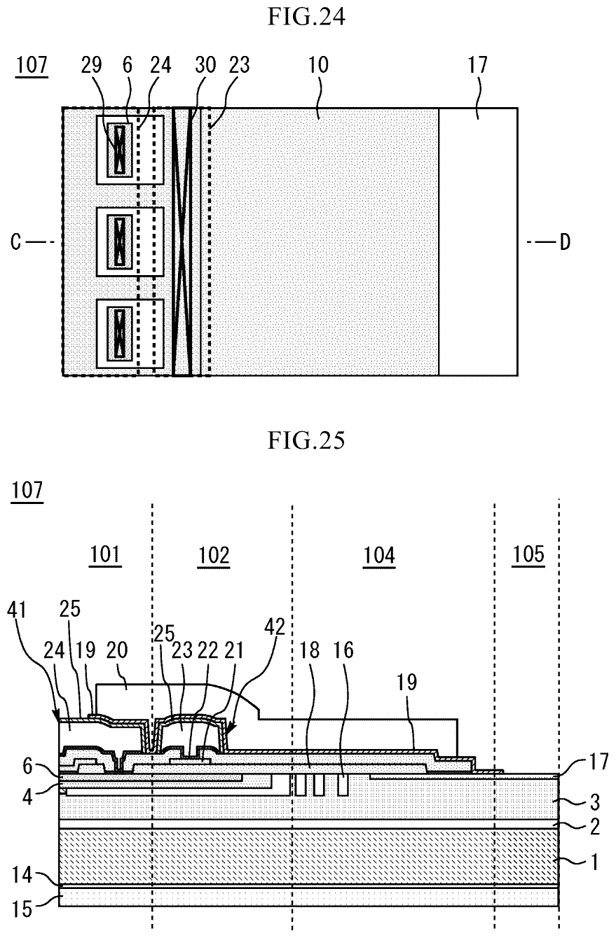

FIG. 24 is an enlarged view of the edge region 107 of the active region 101 according to Embodiment 3. FIG. 25 is a cross-sectional view obtained by cutting FIG. 24 along line C-D. The present embodiment differs from Embodiment 1 in that the metal layer 24 of the pad electrode 41 is also entirely covered with the metal layer 25. The other configuration is similar to that of Embodiment 1.

In this embodiment, the upper and side surfaces of the metal layers 23 and 24 which are Al electrodes are all covered with the metal layer 25 which is a Ti electrode. This prevents the contact portion between the metal layer 23 or the metal layer 24 and the metal layer 25 from being exposed, thereby improving the moisture resistance or acid resistance. Moreover, by covering a part of the gate wiring 42 and the pad electrode 41 with the protective film 19, the moisture resistance or acid resistance can be further improved.

### Embodiment 4

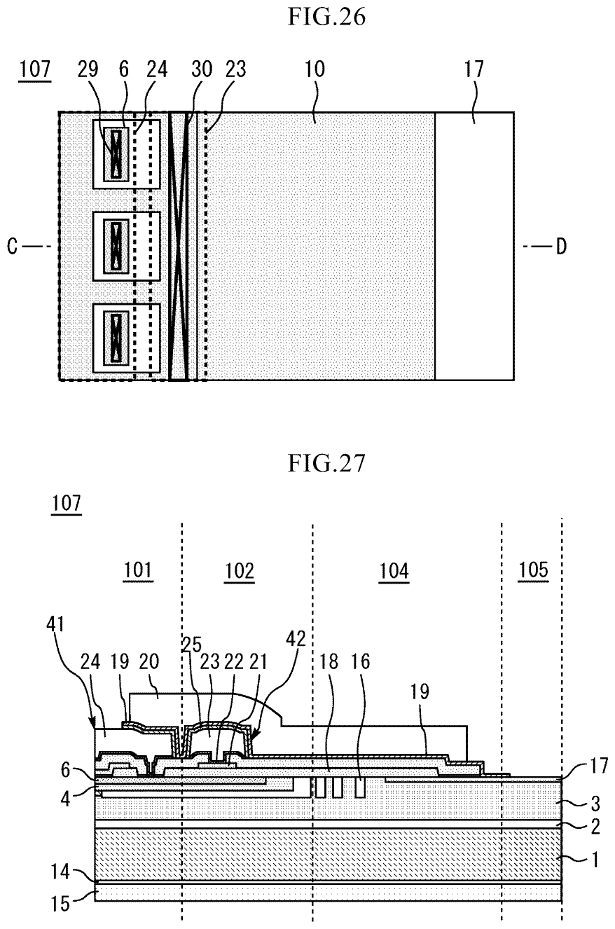

FIG. 26 is an enlarged view of the edge region 107 of the active region 101 according to Embodiment 4. FIG. 27 is a cross-sectional view obtained by cutting FIG. 26 along line C-D. The present embodiment differs from Embodiment 1 in that the contact portion between the metal layer 24 and the metal layer 25 in the pad electrode 41 is exposed from the protective film 19. The other configuration is similar to that of Embodiment 1. In this embodiment, the moisture resistance of the pad electrode 41 is lower than that in Embodiment 1. However, the contact portion between the metal layer 23 and the metal layer 25 in the gate wiring 42 is not exposed to the member provided on the protective film 19. This makes it possible to improve moisture resistance or acid resistance in areas susceptible to the effects of temperature, humidity, and electric fields.

### Embodiment 5

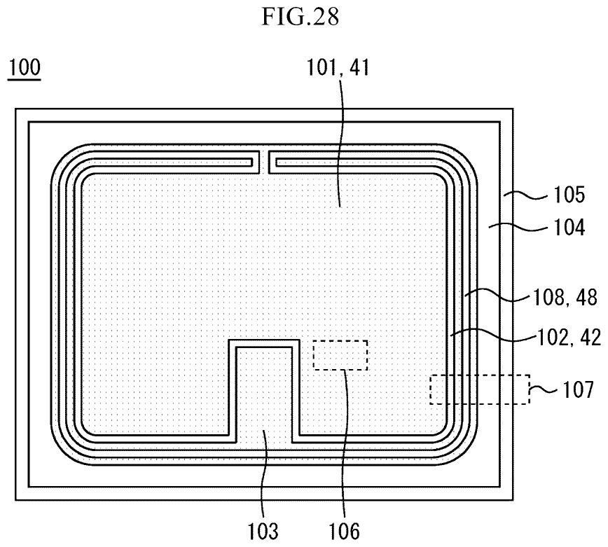

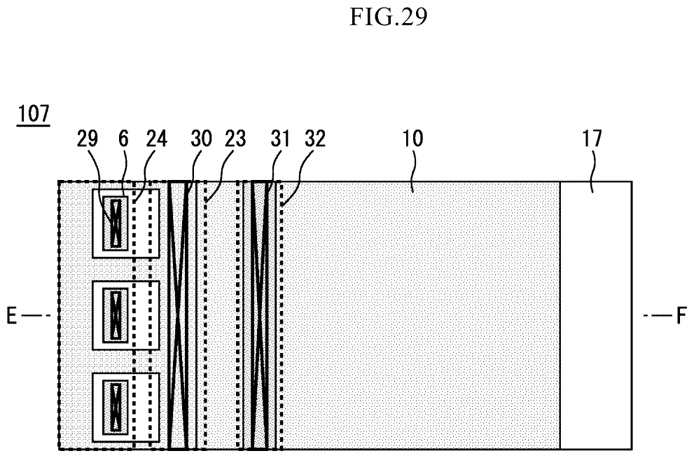

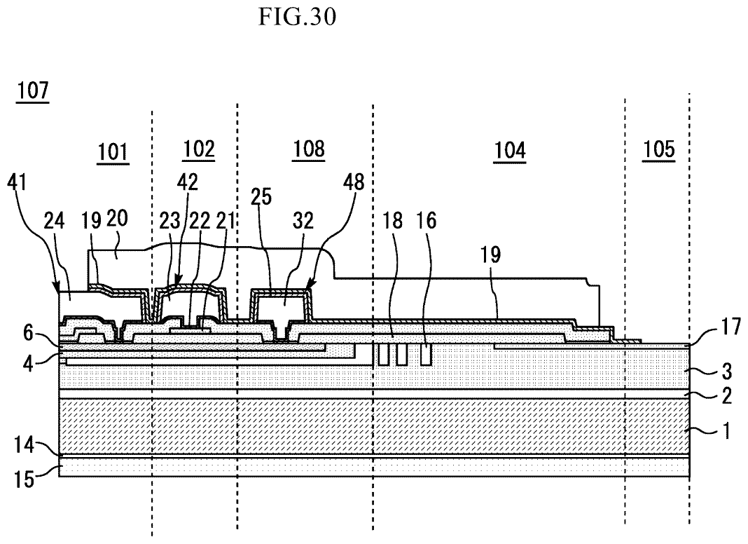

FIG. 28 is a plan view of a semiconductor device 100 according to Embodiment 5. FIG. 29 is an enlarged view of the edge region 107 of the active region 101 according to Embodiment 5. FIG. 30 is a cross-sectional view obtained by cutting FIG. 29 along line E-F. In this embodiment, a source liner wiring region 108 is provided between the gate wiring region 102 and the termination region 104. The source liner wiring region 108 is a region of the semiconductor substrate 1 where a source liner wiring 48 is provided.

In the source liner wiring region 108, a metal layer 32 which is an Al electrode is formed on the barrier metal layer 22. The metal layer 25 made of Ti is formed on the metal layer 32. The barrier metal layer 22, the metal layer 32, and the metal layer 25 provided on the metal layer 32 constitute the source liner wiring 48. The source liner wiring 48 is connected to the well layer 4 and the contact layer 6 through a contact hole 31. The source liner wiring 48 is connected to the source electrode of the active region 101.

In this embodiment, in the source liner wiring 48, the upper surface and both side surfaces of the metal layer 32 are entirely covered with the metal layer 25. Therefore, the contact portion between the metal layer 32 and the metal layer 25 is not exposed to the member provided on the protective film 19. Furthermore, the upper surface and both side surfaces of the source liner wiring 48 are entirely covered with a protective film 19. This can improve the moisture resistance or acid resistance.

In this embodiment, the source liner wiring 48 is the wiring provided closest to the termination region 104. For this reason, in consideration of the intrusion path of moisture and the electric field distribution in the termination region 104, in addition to the gate wiring 42, the source liner wiring 48 is also protected by the metal layer 25 and the protective film 19.

It is also possible to protect only one of the gate wiring 42 and the source liner wiring 48. Moreover, in the present embodiment, an example has been shown in which a source wiring is provided in the wiring region, but in the case where the semiconductor device 100 is an IGBT, an emitter wiring may be provided.

Meanwhile, technical features explained in each embodiment may be appropriately combined to use.

Hereinafter, various aspects of the present disclosure will be collectively described as appendixes.

### (Appendix 1)

A semiconductor device comprising:
a semiconductor substrate;
wiring provided on the semiconductor substrate; and
a protective film covering at least a portion of the wiring;
wherein the wiring include a first metal layer and a second metal layer provided on the first metal layer, the second metal layer including a metal having higher moisture resistance or acid resistance than the first metal layer, and
a contact portion between the first metal layer and the second metal layer in the wiring is not exposed to a member provided on the protective film.

### (Appendix 2)

The semiconductor device according to appendix 1, wherein the semiconductor substrate includes an active region, a wiring region outside the active region, and a termination region outside the wiring region, and
the wiring is provided in the wiring region.

### (Appendix 3)

A semiconductor device comprising:
a semiconductor substrate including an active region, a wiring region outside the active region, and a termination region outside the wiring region;
a wiring provided on the wiring region; and
a protective film covering at least a portion of the wiring;
wherein the wiring include a first metal layer and a second metal layer provided on the first metal layer, the second metal layer including a metal having higher moisture resistance or acid resistance than the first metal layer; and
the protective film is provided from an upper surface of the second metal layer to both side surfaces of the first metal layer.

### (Appendix 4)

The semiconductor device according to appendix 3, wherein a contact portion between the first metal layer and the second metal layer in the wiring is not exposed to a member provided on the protective film.

### (Appendix 5)

The semiconductor device according to any one of appendixes 2 to 4, wherein the wiring is wiring provided closest to the termination region in the wiring region.

### (Appendix 6)

The semiconductor device according to any one of appendixes 1 to 5, wherein an upper surface and both side surfaces of the first metal layer are entirely covered with the second metal layer.

### (Appendix 7)

The semiconductor device according to any one of appendixes 2 to 5, further comprising a pad electrode including a third metal layer provided on the active region, and a fourth metal layer provided on the third metal layer, the fourth metal layer including a metal having higher moisture resistance or acid resistance than the third metal layer,
wherein a pad opening is formed in the pad electrode, in which the third metal layer is exposed from the fourth metal layer, and
a contact portion between the third metal layer and the fourth metal layer facing the pad opening is covered with the protective film.

### (Appendix 8)

The semiconductor device according to any one of appendixes 1 to 7, wherein the wiring is a gate wiring.

### (Appendix 9)

The semiconductor device according to any one of appendixes 1 to 7, wherein the wiring is a source wiring or an emitter wiring.

### (Appendix 10)

The semiconductor device according to any one of appendixes 1 to 9, wherein the second metal layer contains Ti, Au or Pt.

### (Appendix 11)

The semiconductor device according to any one of appendixes 1 to 10, wherein the first metal layer contains Al or Cu.

### (Appendix 12)

The semiconductor device according to any one of appendixes 1 to 11, further comprising a polyimide film provided on the protective film.

### (Appendix 13)

The semiconductor device according to appendix 12, wherein the polyimide film covers a corner of the wiring.

### (Appendix 14)

The semiconductor device according to any one of appendixes 1 to 13, wherein the protective film is a nitride film or an oxide film.

### (Appendix 15)

The semiconductor device according to any one of appendixes 1 to 14, wherein the semiconductor substrate is made with a wide band gap semiconductor.

### (Appendix 16)

The semiconductor device according to appendix 15, wherein the wide band gap semiconductor is silicon carbide, a gallium nitride-based material or diamond.

### (Appendix 17)

A semiconductor device comprising:
a semiconductor substrate;
a pad electrode provided on the semiconductor substrate; and
a protective film provided on the pad electrode;
wherein the pad electrode includes a first metal layer and a second metal layer provided on the first metal layer, the second metal layer including a metal having higher moisture resistance or acid resistance than the first metal layer;
a pad opening is formed in the pad electrode, in which the first metal layer is exposed from the second metal layer; and
a contact portion between the first metal layer and the second metal layer facing the pad opening is covered with the protective film.

In the semiconductor device according to the first disclosure, the contact portion between the first metal layer and the second metal layer is not exposed to the member provided on the protective film. Therefore, the moisture resistance or acid resistance can be improved.

In the semiconductor device according to the second disclosure, a protective film is provided from the upper surface of the second metal layer to both side surfaces of the first metal layer. Therefore, the moisture resistance or acid resistance can be improved.

In the semiconductor device according to the third disclosure, the contact portion between the first metal layer and the second metal layer facing the pad opening is covered with a protective film. Therefore, the moisture resistance or acid resistance can be improved.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2024-229253, filed on Dec. 25, 2024 including specification, claims, drawings and summary, on which the Convention priority of the present application is based, are incorporated herein by reference in its entirety.

1. A semiconductor device comprising:
a semiconductor substrate;
wiring provided on the semiconductor substrate; and
a protective film covering at least a portion of the wiring;
wherein the wiring include a first metal layer and a second metal layer provided on the first metal layer, the second metal layer including a metal having higher moisture resistance or acid resistance than the first metal layer, and
a contact portion between the first metal layer and the second metal layer in the wiring is not exposed to a member provided on the protective film.

2. The semiconductor device according to claim 1, wherein the semiconductor substrate includes an active region, a wiring region outside the active region, and a termination region outside the wiring region, and
the wiring is provided in the wiring region.

3. A semiconductor device comprising:
a semiconductor substrate including an active region, a wiring region outside the active region, and a termination region outside the wiring region;
a wiring provided on the wiring region; and
a protective film covering at least a portion of the wiring;
wherein the wiring include a first metal layer and a second metal layer provided on the first metal layer, the second metal layer including a metal having higher moisture resistance or acid resistance than the first metal layer; and
the protective film is provided from an upper surface of the second metal layer to both side surfaces of the first metal layer.

4. The semiconductor device according to claim 3, wherein a contact portion between the first metal layer and the second metal layer in the wiring is not exposed to a member provided on the protective film.

5. The semiconductor device according to claim 2, wherein the wiring is wiring provided closest to the termination region in the wiring region.

6. The semiconductor device according to claim 1, wherein an upper surface and both side surfaces of the first metal layer are entirely covered with the second metal layer.

7. The semiconductor device according to claim 2, further comprising a pad electrode including a third metal layer provided on the active region, and a fourth metal layer provided on the third metal layer, the fourth metal layer including a metal having higher moisture resistance or acid resistance than the third metal layer,
wherein a pad opening is formed in the pad electrode, in which the third metal layer is exposed from the fourth metal layer, and
a contact portion between the third metal layer and the fourth metal layer facing the pad opening is covered with the protective film.

8. The semiconductor device according to claim 1, wherein the wiring is a gate wiring.

9. The semiconductor device according to claim 1, wherein the wiring is a source wiring or an emitter wiring.

10. The semiconductor device according to claim 1, wherein the second metal layer contains Ti, Au or Pt.

11. The semiconductor device according to claim 1, wherein the first metal layer contains Al or Cu.

12. The semiconductor device according to claim 1, further comprising a polyimide film provided on the protective film.

13. The semiconductor device according to claim 12, wherein the polyimide film covers a corner of the wiring.

14. The semiconductor device according to claim 1, wherein the protective film is a nitride film or an oxide film.

15. The semiconductor device according to claim 1, wherein the semiconductor substrate is made with a wide band gap semiconductor.

16. The semiconductor device according to claim 15, wherein the wide band gap semiconductor is silicon carbide, a gallium nitride-based material or diamond.

17. A semiconductor device comprising:
a semiconductor substrate;
a pad electrode provided on the semiconductor substrate; and
a protective film provided on the pad electrode;
wherein the pad electrode includes a first metal layer and a second metal layer provided on the first metal layer, the second metal layer including a metal having higher moisture resistance or acid resistance than the first metal layer;
a pad opening is formed in the pad electrode, in which the first metal layer is exposed from the second metal layer; and
a contact portion between the first metal layer and the second metal layer facing the pad opening is covered with the protective film.

18. The semiconductor device according to claim 3, wherein the wiring is wiring provided closest to the termination region in the wiring region.

19. The semiconductor device according to claim 3, wherein an upper surface and both side surfaces of the first metal layer are entirely covered with the second metal layer.

20. The semiconductor device according to claim 3, further comprising a pad electrode including a third metal layer provided on the active region, and a fourth metal layer provided on the third metal layer, the fourth metal layer including a metal having higher moisture resistance or acid resistance than the third metal layer,
wherein a pad opening is formed in the pad electrode, in which the third metal layer is exposed from the fourth metal layer, and
a contact portion between the third metal layer and the fourth metal layer facing the pad opening is covered with the protective film.

21. The semiconductor device according to claim 3, wherein the wiring is a gate wiring.

22. The semiconductor device according to claim 3, wherein the wiring is a source wiring or an emitter wiring.

23. The semiconductor device according to claim 3, wherein the second metal layer contains Ti, Au or Pt.

24. The semiconductor device according to claim 3, wherein the first metal layer contains Al or Cu.

25. The semiconductor device according to claim 3, further comprising a polyimide film provided on the protective film.

26. The semiconductor device according to claim 25, wherein the polyimide film covers a corner of the wiring.

27. The semiconductor device according to claim 3, wherein the protective film is a nitride film or an oxide film.

28. The semiconductor device according to claim 3, wherein the semiconductor substrate is made with a wide band gap semiconductor.

29. The semiconductor device according to claim 28, wherein the wide band gap semiconductor is silicon carbide, a gallium nitride-based material or diamond.
